(19) United States
(12) Patent Application Publication
(10) Pub. No.: US 2019/0043438 A1
(43) Pub. Date: Feb. 7, 2019

(54) DISPLAY DEVICE AND CONTROL METHOD THEREFOR

(71) Applicant: Sharp Kabushiki Kaisha, Sakai City, Osaka (JP)

(72) Inventor: Toshihiro YANAGI, Sakai City (JP)

(21) Appl. No.: 16/085,600

(22) PCT Filed: Apr. 20, 2016
(86) PCT No.: PCT/JP2016/062457

§ 371 Date: Sep. 17, 2018

(51) Int. Cl. G09G 3/36; H01L 27/12; G02F 1/1368; G02F 1/1335

(52) U.S. Cl. CPC G09G 3/3677; H01L 27/124; H01L 27/1225; G02F 1/1368; G09G 2300/0439; G09G 3/3614; G02F 1/133603; G09G 2300/0426; G09G 3/3688

(57) ABSTRACT

In a liquid crystal display device, a frame period is classified into a scanning frame period and a suspend frame period. A panel drive circuit writes a voltage in accordance with a video signal to a pixel circuit in a liquid crystal panel in a scanning period Ts set in the scanning frame period. A backlight drive circuit makes a backlight turn on in a backlight turn-on period Ton set in the scanning frame period and the suspend frame period, and makes the backlight turn off otherwise. In the scanning frame period, the backlight turn-on period Ton is set after the scanning period Ts, preferably after a time point when a longest response time of the pixel circuit elapses from an end of the scanning period Ts. With this, a flicker is suppressed in a display device performing a suspend drive.

### TECHNICAL FIELD

The present invention relates to a display device such as a liquid crystal display device, and more particularly to a display device having a function of suspending driving of a display panel, and a control method therefor.

### BACKGROUND ART

In a conventional and typical display device, a display panel is driven at a frame frequency of 60 Hz. As a number of times the display panel is driven increases, power consumption of the display device increases. Thus, as a method for reducing the power consumption of the display device, there is known a method in which driving of the display panel is suspended when a same image is displayed continuously. This method is called a suspend drive, a low frequency drive, an intermittent drive, or the like.

A display device performing the suspend drive has a problem that a flicker occurs in a display screen. FIG. 10 is a diagram showing human flicker sensitivity. As shown in FIG. 10, a human hardly recognizes the flicker when a flicker frequency is high, but recognizes the flicker when the flicker frequency is not more than a certain level Fc (called a critical flicker frequency). The critical flicker frequency Fc is about 40 to 45 Hz, which varies depending on individuals and physical conditions. Thus, when the display panel is driven at a frequency lower than 45 Hz in the display device performing the suspend drive, the flicker occurs in the display screen and display quality degrades.

In the following, a liquid crystal display device performing the suspend drive will be considered. In order to reduce an amplitude of an output voltage of a data line drive circuit, some liquid crystal display devices perform a common inversion drive in which a polarity of a voltage applied to a common electrode is inverted every frame period. However, when the common inversion drive is performed, the flicker is likely to occur. Thus, in recent years, liquid crystal display devices which perform a common DC drive in which a fixed voltage is applied to the common electrode instead of the common inversion drive are increasing in order to suppress the flicker.

Furthermore, as a method for suppressing the flicker, there is known a method of configuring a pixel circuit in the liquid crystal display device, using a transistor having good off-leak characteristics (having smaller off-leakage current). For example, a transistor having a semiconductor layer formed of an oxide semiconductor may be used as a transistor included in the pixel circuit. As the oxide semiconductor, indium gallium zinc oxide (InGaZnO) including indium (In), gallium (Ga), and zinc (Zn) maybe used, for example. According to this method, it is possible to stably hold a voltage written to the pixel circuit for a long time and suppress the flicker.

In relation to the present invention, Patent Document 1 describes a liquid crystal display device which makes a backlight turn on and off at an interval of 1/60 second or less in synchronization with a frame period including a scanning period and a hold period. Patent Document 1 also discloses determining a turn-on timing of the backlight considering a delay time (response time of liquid crystal) from when a counter electrode potential is switched to when a luminance of a pixel reaches a level which causes a problem as a flicker. Patent Document 2 discloses a liquid crystal display device which makes a backlight turn off in a writing time of a video signal for one screen and a liquid crystal response time, and makes the backlight turn on in a time before a start of writing the video signal for next one screen, in order to reduce an afterimage of an moving image.

### PRIOR ART DOCUMENTS

### Patent Documents

[Patent Document 1] Japanese Laid-Open Patent Publication No. 2006-178435

[Patent Document 2] Japanese Laid-Open Patent

Publication No. 2000-56738

### SUMMARY OF THE INVENTION

### Problems to be Solved by the Invention

The flicker can be reduced to some extent by applying the above-described conventional flicker suppression method to the liquid crystal display device. However, even if the conventional flicker suppression method is applied to the liquid crystal display device performing the suspend drive, the flicker can not be suppressed completely. The flicker which occurs at this time is considered to be due to an influence of flexo polarization caused by writing a voltage to the pixel circuit. In the conventional liquid crystal display device performing the suspend drive, it is not possible to suppress the flicker caused by writing the voltage to the pixel circuit.

The flexo polarization occurs easily in a lateral electric field type liquid crystal panel. In the lateral electric field type liquid crystal panel, an electric field approximately in a lateral direction is applied to a liquid crystal layer using a pixel electrode and a common electrode formed on an active matrix substrate. As the lateral electric field type, an IPS (In-Plane Switching) type and an FFS (Fringe Field Switching) type are known. Furthermore, an AFFS (Advanced Fringe Field Switching) type is known as a type obtained by improving the FFS type. The lateral electric field type liquid crystal panel has an advantage that a viewing angle is wide, but has a problem that the flexo polarization occurs easily. Thus, when the liquid crystal display device performing the suspend drive is configured using the lateral electric field type liquid crystal panel, the flicker caused by writing the voltage to the pixel circuit occurs easily.

Therefore, an object of the present invention is to suppress the flicker in a display device performing the suspend drive.

### Means for Solving the Problems

According to a first aspect of the present invention, there is provided a display device having a scanning frame period and a suspend frame period, including: a display panel including a plurality of pixel circuits arranged two-dimensionally; a backlight configured to irradiate a back surface of the display panel with light; a panel drive circuit configured to write a voltage in accordance with a video signal to the pixel circuit in a scanning period set in the scanning frame period; and a backlight drive circuit configured to make the backlight turn on in a backlight turn-on period set in the scanning frame period and the suspend frame period, and make the backlight turn off outside the backlight turn-on period, wherein the backlight turn-on period is set after the scanning period in the scanning frame period.

According to a second aspect of the present invention, in the first aspect of the present invention, the backlight turn-on period is set after a time point when a longest response time of the pixel circuit elapses from an end of the scanning period in the scanning frame period.

According to a third aspect of the present invention, in the second aspect of the present invention, the backlight drive circuit is configured to make the backlight turn on and off at a frequency higher than a critical flicker frequency.

According to a fourth aspect of the present invention, in the second aspect of the present invention, the display device further includes a power supply circuit having a heavy load mode in which a power supply conversion efficiency is high at heavy load and a light load mode in which the power supply conversion efficiency is high at light load, and configured to supply a power supply voltage to the panel drive circuit, wherein the power supply circuit is configured to operate in the heavy load mode in the scanning period and operate in the light load mode in the backlight turn-on period.

According to a fifth aspect of the present invention, in the fourth aspect of the present invention, the power supply circuit is configured to operate in the light load mode in a period from when a predetermined time elapses from the end of the scanning period to a start of the backlight turn-on period.

According to a sixth aspect of the present invention, in the second aspect of the present invention, the display device has a moving image mode in which only the scanning frame period appears and a low frequency drive mode in which the scanning frame period and the suspend frame period appear in a mixed manner.

According to a seventh aspect of the present invention, in the second aspect of the present invention, the display panel is a liquid crystal panel.

According to an eighth aspect of the present invention, in the seventh aspect of the present invention, the liquid crystal panel is a lateral electric field type liquid crystal panel.

According to a ninth aspect of the present invention, in the eighth aspect of the present invention, the liquid crystal panel includes the plurality of pixel circuits each including a transistor, and the transistor includes a semiconductor layer formed using an oxide semiconductor including indium, gallium, and zinc.

According to a tenth aspect of the present invention, in the second aspect of the present invention, the display panel includes the plurality of pixel circuits each including a transistor, and the transistor includes a semiconductor layer formed using an oxide semiconductor including indium, gallium, and zinc.

According to an eleventh aspect of the present invention, there is provided a method for controlling a display device including a display panel including a plurality of pixel circuits arranged two-dimensionally and a backlight for irradiating aback surface of the display panel with light, and having a scanning frame period and a suspend frame period, the method including: writing a voltage in accordance with a video signal to the pixel circuit in a scanning period set in the scanning frame period; and making the backlight turn on in a backlight turn-on period set in the scanning frame period and the suspend frame period, and making the backlight turn off outside the backlight turn-on period, wherein the backlight turn-on period is set after the scanning period in the scanning frame period.

According to a twelfth aspect of the present invention, in the eleventh aspect of the present invention, the backlight turn-on period is set after a time point when a longest response time of the pixel circuit elapses from an end of the scanning period in the scanning frame period.

According to a thirteenth aspect of the present invention, in the twelfth aspect of the present invention, in making the backlight turn on and off, the backlight is made to turn on and off at a frequency higher than a critical flicker frequency.

According to a fourteenth aspect of the present invention, in the twelfth aspect of the present invention, the display device further includes a power supply circuit having a heavy load mode in which a power supply conversion efficiency is high at heavy load and a light load mode in which the power supply conversion efficiency is high at light load, and configured to supply a power supply voltage to the panel drive circuit, and the method further includes making the power supply circuit operate in the heavy load mode in the scanning period and operate in the light load mode in the backlight turn-on period.

According to a fifteenth aspect of the present invention, in the fourteenth aspect of the present invention, in making the power supply circuit operate, the power supply circuit is made to operate in the light load mode in a period from when a predetermined time elapses from the end of the scanning period to a start of the backlight turn-on period.

According to a sixteenth aspect of the present invention, in the twelfth aspect of the present invention, the display device has a moving image mode in which only the scanning frame period appears and a low frequency drive mode in which the scanning frame period and the suspend frame period appear in a mixed manner.

According to a seventeenth aspect of the present invention, in the twelfth aspect of the present invention, the display panel is a liquid crystal panel.

According to an eighteenth aspect of the present invention, in the seventeenth aspect of the present invention, the liquid crystal panel is a lateral electric field type liquid crystal panel.

According to a nineteenth aspect of the present invention, in the eighteenth aspect of the present invention, the liquid crystal panel includes the plurality of pixel circuits each including a transistor, and the transistor includes a semiconductor layer formed using an oxide semiconductor including indium, gallium, and zinc.

According to a twentieth aspect of the present invention, in the twelfth aspect of the present invention, the display panel includes the plurality of pixel circuits each including a transistor, and the transistor includes a semiconductor layer formed using an oxide semiconductor including indium, gallium, and zinc.

### Effects of the Invention

According to the first or eleventh aspect of the present invention, in the scanning frame period, the backlight turns off in the scanning period, and turns on in the backlight turn-on period after the scanning period. It is possible to suppress a flicker which is considered to be due to an influence of flexo polarization caused by writing a voltage to the pixel circuit, by making the backlight turn off when writing the voltage to the pixel circuit in this manner.

According to the second or twelfth aspect of the present invention, in the scanning frame period, the backlight turns off continuously until a response of the pixel circuit is completed even after the end of the scanning period. It is possible to display an image without being affected by a previous frame image, by making the backlight turn off until the response of the pixel circuit is completed even after writing the voltage to the pixel circuit in this manner.

According to the third or thirteenth aspect of the present invention, the backlight turns on and off at the frequency higher than the critical flicker frequency. Therefore, a flicker caused by blinking of the backlight can be suppressed.

According to the fourth or fourteenth aspect of the present invention, it is possible to reduce power consumption of the display device by switching an operation mode of the power supply circuit between the heavy load mode and the low load mode in accordance with an operation state of the panel drive circuit. Furthermore, since a period in which the power supply circuit operates in the heavy load mode and the turn-on period of the backlight do not overlap, a peak current can be suppressed. Therefore, it is possible to downsize a system power supply circuit connected to the power supply circuit and the backlight drive circuit, and prevent degradation of a battery connected to the system power supply circuit.

According to the fifth or fifteenth aspect of the present invention, the power consumption of the display device can be further reduced, since the power supply circuit operates in the light load mode in the period from the end of the scanning period to the backlight turn-on period in the scanning frame period.

According to the sixth or sixteenth aspect of the present invention, it is possible to suppress the flicker which is considered to be due to the influence of the flexo polarization and display the image without being affected by the previous frame image, in the display device which operates in the moving image mode when a change in the image is large and operates in the low frequency drive mode when the change in the image is small.

According to the seventh or seventeenth aspect of the present invention, it is possible to suppress the flicker which is considered to be due to the influence of the flexo polarization and display the image without being affected by the previous frame image, in the liquid crystal display device performing the suspend drive.

According to the eighth or eighteenth aspect of the present invention, it is possible to suppress the flicker which is considered to be due to the influence of the flexo polarization and display the image without being affected by the previous frame image, in the liquid crystal display device including the lateral electric field type liquid crystal panel in which the flexo polarization occurs easily and performing the suspend drive.

According to the ninth or nineteenth aspect of the present invention, it is possible to suppress the flicker which is considered to be due to the influence of the flexo polarization and a flicker caused by a leakage current of the transistor and display the image without being affected by the previous frame image, by providing to the pixel circuit the transistor having the semiconductor layer formed using the oxide semiconductor including indium, gallium, and zinc, in the liquid crystal display device including the lateral electric field type liquid crystal panel in which the flexo polarization occurs easily and performing the suspend drive.

According to the tenth or twentieth aspect of the present invention, the flicker caused by the leakage current of the transistor can be suppressed, by providing to the pixel circuit the transistor having the semiconductor layer formed using the oxide semiconductor including indium, gallium, and zinc.

### BRIEF DESCRIPTION OF THE DRAWINGS

FIG. 1 is a block diagram showing a configuration of a liquid crystal display device according to an embodiment of the present invention.

FIG. 2 is a timing chart in a low frequency drive mode in the liquid crystal display device shown in FIG. 1.

FIG. 3 is a timing chart in a moving image mode in the liquid crystal display device shown in FIG. 1.

FIG. 4 is a timing chart when a display color is changed in the low frequency drive mode in the liquid crystal display device shown in FIG. 1.

FIG. 5 is a timing chart when the low frequency drive mode is changed to the moving image mode in the liquid crystal display device shown in FIG. 1.

FIG. 6 is a diagram showing display screens in backlight turn-on periods shown in FIG. 4.

FIG. 7 is a diagram showing display screens in backlight turn-on periods shown in FIG. 5.

FIG. 8 is a timing chart when a display color is changed in a liquid crystal display device according to a comparative example.

FIG. 9 is a diagram showing display screens in backlight turn-on periods shown in FIG. 8.

FIG. 10 is a diagram showing human flicker sensitivity.

### MODES FOR CARRYING OUT THE INVENTION

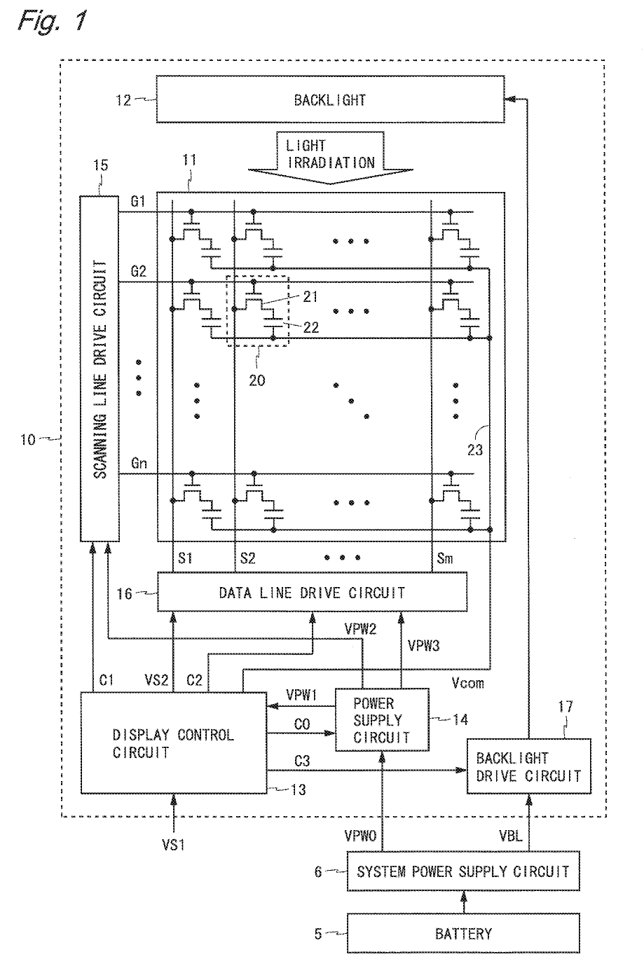

FIG. 1 is a block diagram showing a configuration of a liquid crystal display device according to an embodiment of the present invention. A liquid crystal display device 10 shown in FIG. 1 includes a liquid crystal panel 11, a backlight 12, a display control circuit 13, a power supply circuit 14, a scanning line drive circuit 15, a data line drive circuit 16, and a backlight drive circuit 17. The liquid crystal display device 10 operates, for example, with a battery 5 and a system power supply circuit 6 arranged externally as power sources. In the following, it is assumed that m and n are integers not less than 2, i is an integer not less than 1 and not more than n, and j is an integer not less than 1 and not more than m.

The liquid crystal panel 11 includes n scanning lines G1 to Gn, m data lines S1 to Sm, and (m×n) pixel circuits 20. The scanning lines G1 to Gn are arranged in parallel with each other. The data lines S1 to Sm are arranged in parallel with each other so as to intersect with the scanning lines G1 to Gn perpendicularly. The scanning lines G1 to Gn and the data lines S1 to Sm intersect at (m×n) positions. The (m×n) pixel circuits 20 are arranged two-dimensionally corresponding to intersections of the scanning lines G1 to Gn and the data lines S1 to Sm.

A mode and a type of the liquid crystal panel 11 are arbitrary. For example, the type of the liquid crystal panel 11 may be either a vertical electric field type or a lateral electric field type. Furthermore, the lateral electric field type may be any one of an IPS type, a FFS type, and an AFFS type.

A lateral electric field type liquid crystal panel has an advantage that a viewing angle is wide, but has a problem that flexo polarization occurs easily. When the lateral electric field type liquid crystal panel is used as the liquid crystal panel 11, effects described later become remarkable.

The pixel circuit 20 includes a thin film transistor (hereinafter referred to as TFT) 21 and a liquid crystal capacitance 22. The TFT 21 is an N-channel type transistor. In the pixel circuit 20 in an i-th row and a j-th column, a gate terminal of the TFT 21 is connected to a scanning line Gi, a source terminal of the TFT 21 is connected to a data line Sj, and a drain terminal of the TFT 21 is connected to one electrode of the liquid crystal capacitance 22. The other electrode of the liquid crystal capacitance 22 is connected to a common electrode 23 common to all of the pixel circuits 20. The pixel circuit 20 is connected to one scanning line and one data line in this manner. Note that the pixel circuit 20 may include an auxiliary capacitance in parallel with the liquid crystal capacitance 22.

It is preferable that a transistor having good off-leak characteristics be used as the TFT 21. For example, a transistor having a semiconductor layer formed of an oxide semiconductor may be used as the TFT 21. For example, indium gallium zinc oxide (InGaZnO) including indium (In), gallium (Ga), and zinc (Zn) may be used as the oxide semiconductor. It is possible to suppress a flicker caused by a leakage current of the transistor, by providing to the pixel circuit 20 the TFT 21 having the semiconductor layer formed using the oxide semiconductor including indium, gallium, and zinc.

The backlight 12 is provided on a back surface side of the liquid crystal panel 11, and irradiates a back surface of the liquid crystal panel 11 with light. As described later, the backlight 12 emits light for a predetermined time once in one frame period. For example, a direct type backlight including a plurality of light emitting diodes (hereinafter referred to as LEDs) arranged two-dimensionally is used as the backlight 12. The backlight 12 which turns on and off in the frame period can be configured by using the LEDs.

The display control circuit 13 is a control circuit of the liquid crystal display device 10. A video signal VS1 is input from an outside of the liquid crystal display device 10 to the display control circuit 13. Based on the video signal VS1, the display control circuit 13 outputs a control signal C0 to the power supply circuit 14, outputs a control signal C1 to the scanning line drive circuit 15, outputs a control signal C2 and a video signal VS2 to the data line drive circuit 16, and outputs a control signal C3 to the backlight drive circuit 17. Furthermore, the display control circuit 13 applies a fixed common electrode voltage Vcom to the common electrode 23.

A predetermined power supply voltage is supplied from the battery 5 to the system power supply circuit 6. Based on the power supply voltage supplied from the battery 5, the system power supply circuit 6 supplies a power supply voltage VPWO to the power supply circuit 14, and supplies a power supply voltage VBL to the backlight drive circuit 17.

The power supply circuit 14 is a DC/DC converter for converting the power supply voltage VPWO supplied from the system power supply circuit 6 to a power supply voltage VPW1 supplied to the display control circuit 13, a power supply voltage VPW2 supplied to the scanning line drive circuit 15, and a power supply voltage VPW3 supplied to the data line drive circuit 16. The power supply voltage VPW2 includes a scanning ON voltage with which the TFT 21 turns on and a scanning OFF voltage with which the TFT 21 turns off. The power supply circuit 14 has, as operation modes, a heavy load mode in which a power supply conversion efficiency is high at heavy load and a light load mode in which the power supply conversion efficiency is high at light load. The control signal C0 supplied to the power supply circuit 14 is switched between a high level indicating the heavy load mode and a low level indicating the light load mode. When the control signal C0 is at the high level, the power supply circuit 14 operates in the heavy load mode and performs a voltage conversion using a method in which the power supply conversion efficiency is high at heavy load. When the control signal C0 is at the low level, the power supply circuit 14 operates in the light load mode and performs the voltage conversion using a method in which the power supply conversion efficiency is high at light load. Power consumption of the liquid crystal display device 10 is less in the light load mode than in the heavy load mode.

The scanning line drive circuit 15 drives the scanning lines G1 to Gn based on the control signal C1. More specifically, the scanning line drive circuit 15 sequentially selects one scanning line from among the scanning lines G1 to Gn based on the control signal C1, and applies a selection voltage (here, a high level voltage) to the selected scanning line for one horizontal period. With this, m pixel circuits 20 connected to the selected scanning line are selected collectively.

The data line drive circuit 16 drives the data lines S1 to Sm based on the control signal C2 and the video signal VS2. More specifically, based on the control signal C2, the data line drive circuit 16 applies m voltages (hereinafter referred to as data voltages) in accordance with the video signal VS2 to the data lines S1 to Sm respectively for one horizontal period. With this, the m data voltages are written to the selected m pixel circuits 20, respectively. Transmittance of the pixel circuit 20 is changed in accordance with the data voltage written to the pixel circuit 20.

The backlight drive circuit 17 drives the backlight 12 based on the control signal C3 and the power supply voltage VBL supplied from the system power supply circuit 6. The control signal C3 supplied to the backlight drive circuit 17 is switched to the high level indicating turn-on of the backlight and the low level indicating turn-off of the backlight. The control signal C3 becomes the high level in a backlight turn-on period Ton (details will be described later). The backlight drive circuit 17 makes the backlight 12 turn on when the control signal C3 is at the high level, and makes the backlight 12 turn off when the control signal C3 is at the low level. It is possible to switch turn-on and turn-off of the backlight 12 easily by using the backlight 12 including the LEDs.

In the liquid crystal display device 10, in order to perform the suspend drive, the frame period is classified into a scanning frame period in which the liquid crystal panel 11 is driven and a suspend frame period in which the liquid crystal panel 11 is not driven. Furthermore, the liquid crystal display device 10 has a moving image mode in which only the scanning frame period appears and a low frequency drive mode in which the scanning frame period and the suspend frame period appear in a mixed manner. The liquid crystal display device 10 is switched to the moving image mode when a movement of an image is large, and is switched to the low frequency drive mode when the movement of the image is small. The video signal VS1 supplied to the display control circuit 13 includes a flag indicating whether a current frame image is changed from a previous frame image. The display control circuit 13 determines whether the frame period is the scanning frame period or the suspend frame period based on the flag and a predetermined period. Note that the display control circuit 13 may determine whether the frame period is the scanning frame period or the suspend frame period by using other methods.

Furthermore, the display control circuit 13 may determine whether it is in the moving image mode or in the low frequency drive mode by using methods other than described above. In a battery-powered mobile device such as a smart phone or a tablet PC, a moving image display and a still image display are selectively performed in accordance with a usage or a usage scene. For example, the moving image display is performed when a movie is played back, and the still image display is performed when viewing a mail, a website, or a photograph. It is possible to reduce power consumption of the liquid crystal display device 10 and greatly increase an operating time by the battery, by operating in the moving image mode when performing the moving image display and operating in the low frequency drive mode when performing the still image display.

In the scanning frame period, the display control circuit 13 switches the control signals C1, C2 to an active level and an inactive level (high level and low level) at predetermined timings. In the scanning frame period, the scanning line drive circuit 15 drives the scanning lines G1 to Gn based on the control signal C1, and the data line drive circuit 16 drives the data lines S1 to Sm based on the control signal C2. In the suspend frame period, the display control circuit 13 fixes the control signals C1, C2 to the inactive level (low level). In the suspend frame period, the scanning line drive circuit 15 does not drive the scanning lines G1 to Gn, and the data line drive circuit 16 does not drive the data lines S1 to Sm.

In this manner, the scanning line drive circuit 15 and the data line drive circuit 16 function as a panel drive circuit for writing a voltage in accordance with the video signal VS2 to the pixel circuit 20 included in the liquid crystal panel 11, in the scanning period Ts set in the scanning frame period. The backlight drive circuit 17 makes the backlight 12 turn on in the backlight turn-on period Ton set in the scanning frame period and the suspend frame period, and makes the backlight 12 turn off outside the backlight turn-on period Ton. Note that all or a part of the panel drive circuit may be integrally formed on the liquid crystal panel 11 together with the pixel circuits 20, or a plurality of semiconductor chips including the panel drive circuit may be mounted on the liquid crystal panel 11.

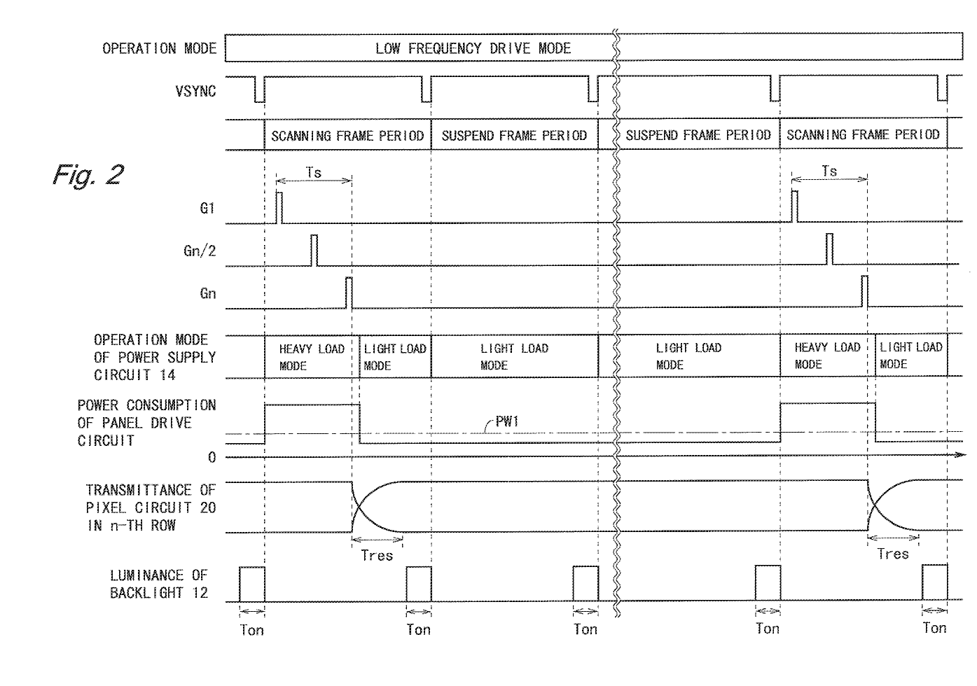

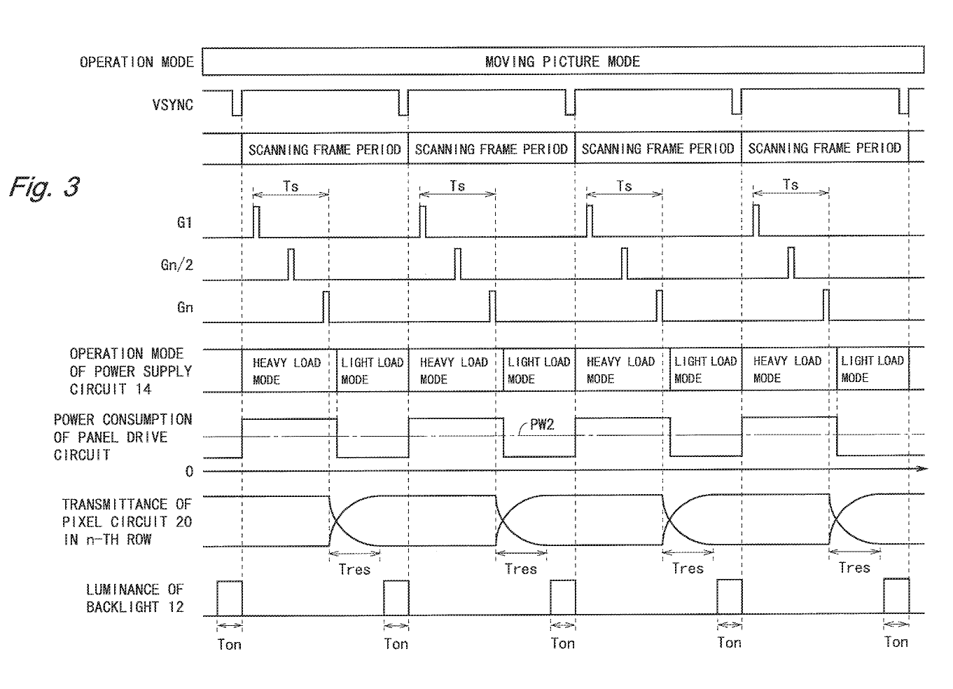

FIGS. 2 and 3 are timing charts of the liquid crystal display device 10. FIG. 2 describes timings in the low frequency drive mode. FIG. 3 describes timings in the moving image mode. In FIGS. 2 and 3, VSYNC represents a vertical synchronization signal included in the video signal VS1.

As shown in FIGS. 2 and 3, the scanning periods Ts are set in the scanning frame period, and the backlight turn-on periods Ton are set before ends of the scanning frame period and the suspend frame period. The display control circuit 13 outputs a high-level control signal C0 in a first half of the scanning frame period, the first half including the scanning period Ts, and outputs a low-level control signal C0 otherwise. The power supply circuit 14 operates in the heavy load mode in the first half of the scanning frame period, and operates in the light load mode otherwise. In this manner, the power supply circuit 14 operates in the heavy load mode in the scanning period Ts, and operates in the light load mode in the backlight turn-on period Ton. Furthermore, the power supply circuit 14 operates in the light load mode in a period from when a predetermined time elapses from an end of the scanning period Ts to a start of the backlight turn-on period Ton. Power consumption of the panel drive circuit is large in the first half of the scanning frame period, and is small otherwise. Thus, an average power consumption (PW1 shown in FIG. 2) of the panel drive circuit in the low frequency drive mode is smaller than an average power consumption (PW2 shown in FIG. 3) of the panel drive circuit in the moving image mode.

In the scanning period Ts, n horizontal periods are set. In an i-th horizontal period, a voltage of the scanning line Gi becomes the high level. At this time, in the pixel circuit 20 connected to the scanning line Gi and the data line Sj, the TFT 21 turns on, and the data voltage applied to the data line Sj is written.

The backlight 12 turns on in the backlight turn-on period Ton, once in one frame period. The backlight turn-on period Ton is set after the scanning period Ts in the scanning frame period. More preferably, the backlight turn-on period Ton is set in the scanning frame period after a time point when a longest response time of the pixel circuit 20 elapses from the end of the scanning period Ts. A position of the backlight turn-on period Ton in the suspend frame period is the same as that in the scanning frame period.

Here, the longest response time of the pixel circuit means the longest time among times from when a voltage is written to the pixel circuit to when a state (here, transmittance) of the pixel circuit sufficiently comes close to a state corresponding to the written voltage. For example, time necessary for a display screen to change from black to white and time necessary for the display screen to change from white to black are measured, and a larger one of the two measured values may be used as the longest response time of the pixel circuit. Furthermore, the longest response time of the pixel circuit may be determined by other methods. Furthermore, the liquid crystal display device 10 may perform an overdrive drive in order to shorten response time of liquid crystal. In this case, time necessary for a state of the pixel circuit to change may be measured with performing the overdrive drive, and the longest response time of the pixel circuit may be determined based on the measured time.

In the liquid crystal display device 10, a period of which length is equal to that of the longest response time of the pixel circuit 20 is referred to as a pixel response period Tres. In the liquid crystal display device 10, the pixel response period Tres is set immediately after the scanning period Ts, and the backlight turn-on period Ton is set immediately after the pixel response period Tres. In the scanning frame period, the backlight 12 turns off in the scanning period Ts and the pixel response period Tres, and turns on in the backlight turn-on period Ton.

Hereinafter, lengths of the scanning period Ts, the pixel response period Tres, and the backlight turn-on period Ton are denoted by Ts, Tres, and Ton respectively, using the same symbols. Furthermore, it is assumed that a turn-on cycle of the backlight 12 is Tx, a turn-on frequency of the backlight 12 is Fx (=1/Tx), and a critical flicker frequency is Fc.

In the liquid crystal display device 10, the lengths of the scanning period Ts, the pixel response period Tres, and the backlight turn-on period Ton are determined so as to satisfy Ts+Tres+Ton≤Tx and Fx>Fc. Especially, it is preferable that Ts+Tres+Ton=Tx be satisfied. Since Fx>Fc is satisfied, the backlight drive circuit 17 makes the backlight 12 turns on and off at a frequency higher than the critical flicker frequency Fc. At this time, a human hardly recognizes a flicker.

For example, it is assumed that Ts=8.3 ms, Tres=10.5 ms, Ton=2 ms, and Ts+Tres+Ton=Tx. In this case, since Tx is 20.8 ms and Fx is approximately 48 Hz, the turn-on frequency Fx of the backlight 12 is larger than the critical flicker frequency Fc. Therefore, when the values of Ts, Tres, and Ton are determined as described above, the human hardly recognizes the flicker.

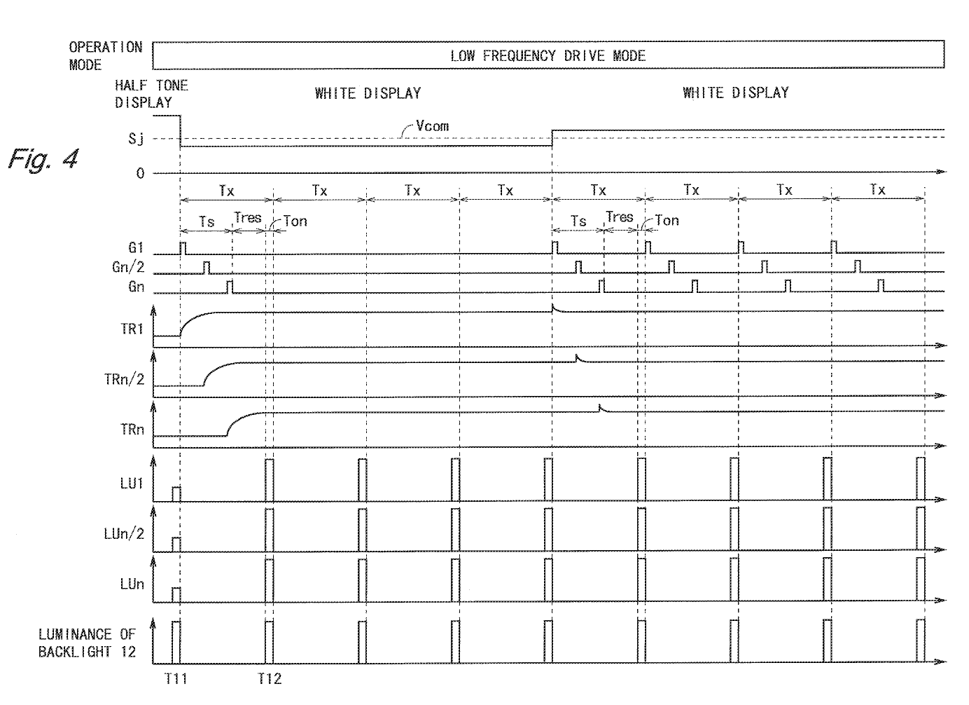

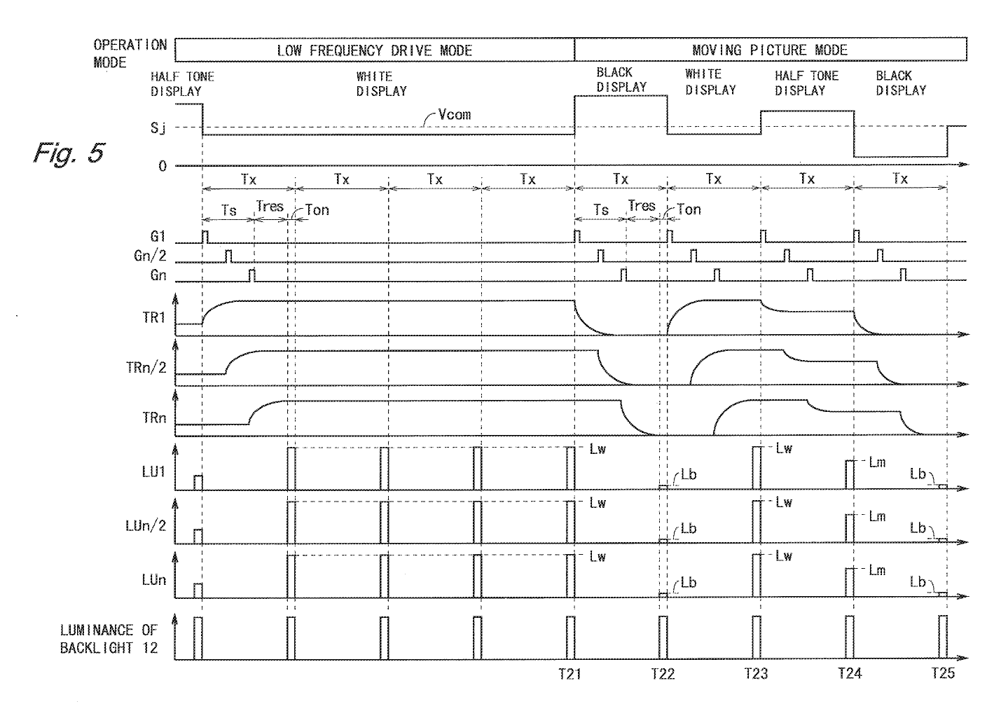

FIGS. 4 and 5 are timing charts of the liquid crystal display device 10. In FIGS. 4 and 5, TRi represents transmittance of the pixel circuit 20 in an i-th row, and LUi represents luminance of the pixel circuit 20 in the i-th row.

Note that, it is assumed in FIGS. 4 and 5 that three suspend frame periods appear after the scanning frame period.

FIG. 4 describes timings when a white display is performed after a half tone display in the low frequency drive mode. In FIG. 4, first and fifth frame periods are the scanning frame periods, and second to fourth and sixth to eighth frame periods are the suspend frame periods. Hereinafter, a case where a voltage is higher than the common electrode voltage Vcom is referred to as“positive polarity”, and a case where the voltage is lower than the common electrode voltage Vcom is referred to as“negative polarity”.

To the data line Sj, a negative polarity data voltage corresponding to white is applied in the first to fourth frame periods, and a positive polarity data voltage corresponding to white is applied in the fifth to eighth frame periods. In the scanning period Ts in the first frame period, the negative polarity data voltage corresponding to white is sequentially written to the pixel circuits 20 in each row. With this, transmittances TR1 to TRn of the pixel circuits 20 in each row are changed toward a level corresponding to white.

The backlight turn-on period Ton is set after the scanning period Ts and the pixel response period Tres. Thus, the transmittances TR1 to TRn of the pixel circuits 20 in each row have already reached the level corresponding to white at a time point when the backlight 12 turns on in the first frame period. Therefore, the luminances LU1 to LUn of the pixel circuits 20 in each row all become the level corresponding to white in the backlight turn-on period Ton in the first frame period.

In the second to fourth frame periods, the data voltage is not written to the pixel circuit 20. Thus, the transmittances TR1 to TRn of the pixel circuits 20 in each row do not change from the level corresponding to white. Therefore, the luminances LU1 to LUn of the pixel circuits 20 in each row all become the level corresponding to white, also in the backlight turn-on periods Ton in the second to fourth frame periods.

In the scanning period Ts in the fifth frame period, the positive polarity data voltage corresponding to white is sequentially written to the pixel circuits 20 in each row. At this time, the transmittances TR1 to TRn of the pixel circuits 20 in each row fluctuate by an influence of writing. However, the transmittances TR1 to TRn of the pixel circuits 20 in each row have already returned to the level corresponding to white at a time point when the backlight 12 turns on in the fifth frame period. Therefore, the luminances LU1 to LUn of the pixel circuits 20 in each row all become the level corresponding to white in the backlight turn-on period Ton in the fifth frame period. As with the backlight turn-on periods Ton in the second to fourth frame periods, the luminances LU1 to LUn of the pixel circuits 20 in each row all become the level corresponding to white, also in the backlight turn-on periods Ton in the fifth to eighth frame periods.

FIG. 5 describes timings when the low frequency drive mode is changed to the moving image mode. In FIG. 5, the operation mode of the liquid crystal display device 10 is the low frequency drive mode before and in the fourth frame period, and is the moving image mode in and after the fifth frame period. The first and fifth to eighth frame periods are the scanning frame periods, and the second to fourth frame periods are the suspend frame periods.

To the data line Sj, the negative polarity data voltage corresponding to white is applied in the first to fourth frame periods, and a positive polarity data voltage corresponding to black, the negative polarity data voltage corresponding to white, a positive polarity data voltage corresponding to half tone, and a negative polarity data voltage corresponding to black are sequentially applied in the fifth to eighth frame periods. The liquid crystal display device 10 operates in a manner similar to the case shown in FIG. 4 before and in the fourth frame period.

The positive polarity data voltage corresponding to black is sequentially written to the pixel circuits 20 in each row in the scanning period Ts in the fifth frame period. With this, the transmittances TR1 to TRn of the pixel circuits 20 in each row are changed toward a level corresponding to black. The transmittances TR1 to TRn of the pixel circuits 20 in each row have already reached the level corresponding to black at a time point when the backlight 12 turns on in the fifth frame period. Therefore, the luminances LU1 to LUn of the pixel circuits 20 in each row all become the level corresponding to black in the backlight turn-on period Ton in the fifth frame period. Note that the influence of writing does not appear in the transmittances TR1 to TRn of the pixel circuits 20 in each row in the scanning period Ts in the fifth frame period.

The negative polarity data voltage corresponding to white, the positive polarity data voltage corresponding to half tone, and the negative polarity data voltage corresponding to black are written sequentially to the pixel circuits 20 in each row in the scanning periods Ts in the sixth to eighth frame periods. The transmittances TR1 to TRn of the pixel circuits 20 in each row have already reached the level corresponding to the written data voltage at a time point when the backlight 12 turns on in the sixth to eighth frame periods. Therefore, the luminances LU1 to LUn of the pixel circuits 20 in each row become the level corresponding to the written data voltage in the backlight turn-on periods Ton in the sixth to eighth frame periods.

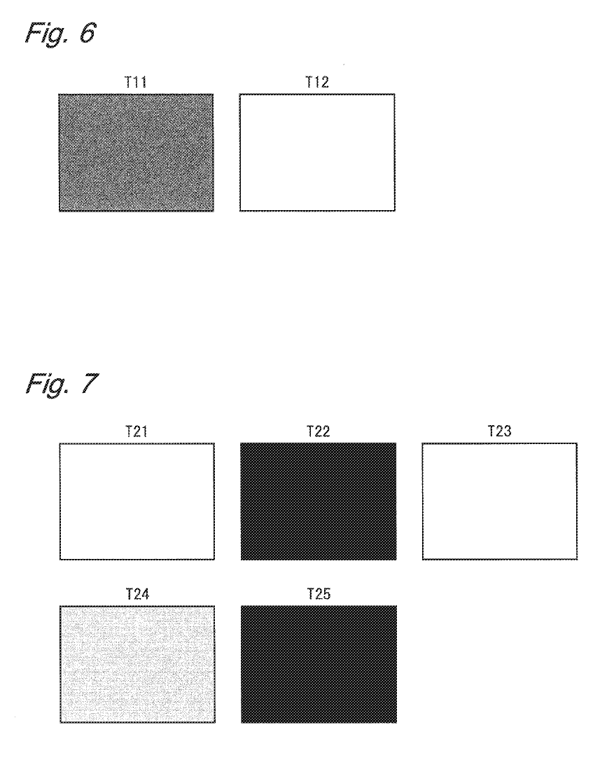

FIG. 6 is a diagram showing display screens in backlight turn-on periods T11, T12 shown in FIG. 4. As shown in FIG. 6, an entire of the display screen becomes half tone in the period T11, and the entire of the display screen becomes white in the period T12. FIG. 7 is a diagram showing display screens in backlight turn-on periods T21 to T25 shown in FIG. 5. As shown in FIG. 7, the entire of the display screen becomes white in the period T21, the entire of the display screen becomes black in the period T22, the entire of the display screen becomes white in the period T23, the entire of the display screen becomes half tone in the period T24, and the entire of the display screen becomes black in the period T25. In this manner, the liquid crystal display device 10 displays an image without being affected by a previous frame image even when an image different from that in a previous frame is displayed, and when the operation mode is changed between the low frequency drive mode and the moving image mode.

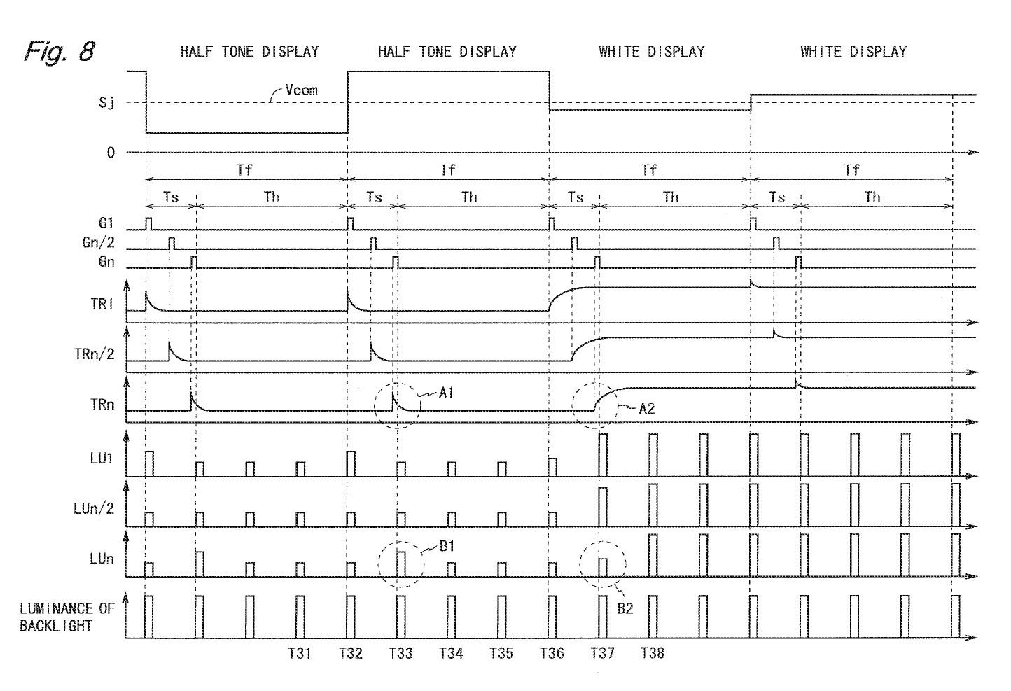

In the following, a liquid crystal display device which makes a backlight turn on at timings described in Patent Document 1 is considered as a comparative example. FIG. 8 is a timing chart of the liquid crystal display device according to the comparative example. FIG. 8 describes timings when the white display is performed after the half tone display.

In the liquid crystal display device according to the comparative example, a frame period Tf is divided into a scanning period Ts and a hold period Th. Backlight turn-on periods are set four times in one frame period, including immediately after a start and immediately after an end of the scanning period Ts. In the liquid crystal display device according to the comparative example, since a backlight turns on in the scanning period Ts, there occurs a flicker which is considered to be due to an influence of the flexo polarization caused by writing a data voltage to a pixel circuit. In FIG. 8, in a period T33 where the backlight turns on, there occurs a change which is considered to be due to an influence of the flexo polarization in a transmittance TRn of the pixel circuit in an n-th row (see a portion surrounded by a broken line A1 in FIG. 8). Thus, there also occurs a change in a luminance LUn of the pixel circuit in the n-th row in the period T33 (see a portion surrounded by a broken line B1 in FIG. 8). Furthermore, at a timing of switching from the half tone display to the white display, in the backlight turn-on period (for example, period T37) set immediately after the end of the scanning period Ts, transmittance of the pixel circuit near the n-th row is still changing (see a portion surrounded by a broken line A2 in FIG. 8). Thus, in the liquid crystal display device according to the comparative example, luminance unevenness occurs together with the flicker in a lower portion of a display screen (see a portion surrounded by a broken line B2 in FIG. 8).

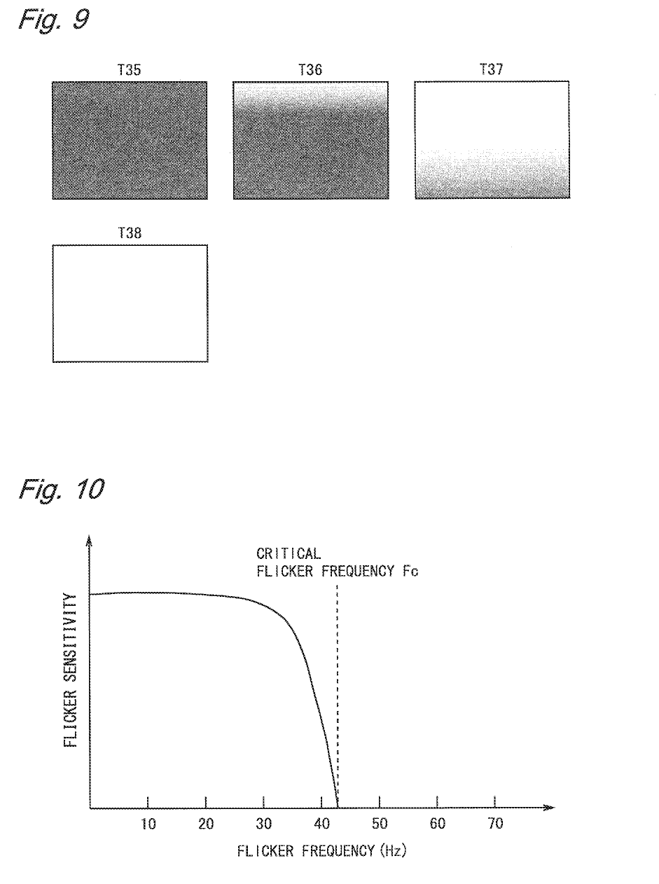

Furthermore, in the backlight turn-on period (for example, period T36) set immediately after the start of the scanning period Ts, transmittance of the pixel circuit near a first row is still changing. In the liquid crystal display device according to the comparative example, display screens in the backlight turn-on periods T35 to T38 shown in FIG. 8 are as shown in FIG. 9. As shown in FIG. 9, an entire of the display screen becomes half tone in the period T35, and the entire of the display screen becomes white in the period T38. However, in the period T36, only an upper portion of the display screen becomes white, and the remaining portion of the display screen remains half tone. In the period T37, an upper half of the display screen becomes white, and a lower half of the display screen becomes a color between half tone and white. In this manner, when displaying an image different from that in a previous frame, the liquid crystal display device according to the comparative example displays an image affected by a previous frame image.

On the contrary, in the liquid crystal display device 10 according to the present embodiment, the backlight 12 turns off in the scanning period Ts. Therefore, according to the liquid crystal display device 10, it is possible to prevent the flicker which is considered to be due to the influence of the flexo polarization caused by writing the data voltage to the pixel circuit 20. Furthermore, the backlight 12 turns off also in the pixel response period Tres set immediately after the scanning period Ts. Therefore, the transmittance of the pixel circuit 20 has already reached the level corresponding to the written data voltage at a time point when the backlight 12 turns on. Therefore, according to the liquid crystal display device 10, the image can be displayed without being affected by the previous frame image.

As described above, the liquid crystal display device 10 according to the present embodiment has the scanning frame period and the suspend frame period, and includes a display panel (liquid crystal panel 11) including the plurality of pixel circuits 20 arranged two-dimensionally, the backlight 12 for irradiating the back surface of the display panel with light, the panel drive circuit (scanning line drive circuit 15 and data line drive circuit 16) for writing the voltage (data voltage) in accordance with the video signal VS2 to the pixel circuit 20 in the scanning period Ts set in the scanning frame period, and the backlight drive circuit 17 for making the backlight 12 turn on in the backlight turn-on period Ton set in the scanning frame period and the suspend frame period, and making the backlight 12 turn off outside the backlight turn-on period Ton. The backlight turn-on period Ton is set after the scanning period Ts in the scanning frame period. In the scanning frame period, the backlight 12 turns off in the scanning period Ts, and turns on in the backlight turn-on period Ton set after the scanning period Ts. It is possible to prevent the flicker which is considered to be due to the influence of the flexo polarization caused by writing the voltage to the pixel circuit 20, by making the backlight 12 turn off when writing the voltage to the pixel circuit 20 in this manner.

Furthermore, the backlight turn-on period Ton is set after the time point when the longest response time of the pixel circuit 20 elapses from the end of the scanning period Ts in the scanning frame period. In the scanning frame period, the backlight 12 turns off continuously until a response of the pixel circuit 20 is completed even after the end of the scanning period Ts. It is possible to display the image without being affected by the previous frame image, by making the backlight 12 turn off until the response of the pixel circuit 20 is completed even after writing the voltage to the pixel circuit 20 in this manner.

Furthermore, the backlight drive circuit 17 makes the backlight 12 turn on and off at a frequency higher than the critical flicker frequency Fc. The backlight 12 turns on and off at the frequency higher than the critical flicker frequency Fc. Therefore, a flicker caused by blinking of the backlight 12 can be prevented.

Furthermore, the liquid crystal display device 10 includes the power supply circuit 14 having the heavy load mode in which the power supply conversion efficiency is high at heavy load and the light load mode in which the power supply conversion efficiency is high at light load, and supplying the power supply voltages VPW2, VPW3 to the panel drive circuit. The power supply circuit 14 operates in the heavy load mode in the scanning period Ts, and operates in the light load mode in the backlight turn-on period Ton. It is possible to reduce power consumption of the liquid crystal display device 10 by switching the operation mode of the power supply circuit 14 in accordance with an operation state of the panel drive circuit in this manner. Furthermore, since a period in which the power supply circuit 14 operates in the heavy load mode and the turn-on period of the backlight 12 do not overlap, a peak current can be suppressed. Therefore, it is possible to downsize the system power supply circuit 6 connected to the power supply circuit 14 and the backlight drive circuit 17, and prevent degradation of the battery 5 connected to the system power supply circuit 6.

Furthermore, the power supply circuit 14 operates in the light load mode in a period from when a predetermined time elapses from the end of the scanning period Ts to the start of the backlight turn-on period Ton. The power consumption of the liquid crystal display device 10 can be further reduced, since the power supply circuit 14 operates in the light load mode in the period from the end of the scanning period Ts to the backlight turn-on period Ton in the scanning frame period. Especially, since the power supply circuit 14 operates in the light load mode for a predetermined period in one frame period even in the moving image mode in which only the scanning frame period appears, the power consumption can be reduced compared with a display device in which a power supply circuit always operates in the heavy load mode in the moving image mode.

Furthermore, the liquid crystal display device 10 has the moving image mode in which only the scanning frame period appears, and the low frequency drive mode in which the scanning frame period and the suspend frame period appear in a mixed manner. Therefore, it is possible to suppress the flicker which is considered to be due to the influence of the flexo polarization and display the image without being affected by the previous frame image, in the display device which operates in the moving image mode when a change in the image is large and operates in the low frequency drive mode when the change in the image is small.

Furthermore, when a lateral electric field type liquid crystal panel is used as the liquid crystal panel 11, effects that the flicker which is considered to be due to the influence of the flexo polarization can be suppressed and the image can be displayed without being affected by the previous frame image become remarkable.

Furthermore, when the liquid crystal panel 11 includes the plurality of pixel circuits 20 each including a transistor (TFT 21), and the transistor has a semiconductor layer formed using an oxide semiconductor including indium, gallium, and zinc, the flicker caused by the leakage current of the transistor can be suppressed.

In the above description, a fixed voltage is applied to the common electrode 23. However, the present invention can be applied to a liquid crystal display device in which a polarity of a voltage applied to the common electrode is inverted every frame period, and a liquid crystal display device adopting a feedback method using an operational amplifier for correcting distortion of the voltage applied to the common electrode. Furthermore, the present invention can be applied to a display device other than the liquid crystal display device, the display device including a backlight.

### INDUSTRIAL APPLICABILITY

Since the display device of the present invention has a feature that the flicker can be suppressed, the display device can be used for a various types of display devices performing the suspend drive, such as a liquid crystal display device performing the suspend drive (in particular, a liquid crystal display device performing the suspend drive using a lateral electric field type liquid crystal panel).

### DESCRIPTION OF REFERENCE CHARACTERS

10: LIQUID CRYSTAL DISPLAY DEVICE

11: LIQUID CRYSTAL PANEL

12: BACKLIGHT

13: DISPLAY CONTROL CIRCUIT

14: POWER SUPPLY CIRCUIT

15: SCANNING LINE DRIVE CIRCUIT

16: DATA LINE DRIVE CIRCUIT

17: BACKLIGHT DRIVE CIRCUIT

20: PIXEL CIRCUIT

21: TFT

22: LIQUID CRYSTAL CAPACITANCE

23: COMMON ELECTRODE

1. A display device having a scanning frame period and a suspend frame period, comprising:
a display panel including a plurality of pixel circuits arranged two-dimensionally;
a backlight configured to irradiate a back surface of the display panel with light;
a panel drive circuit configured to write a voltage in accordance with a video signal to the pixel circuit in a scanning period set in the scanning frame period; and
a backlight drive circuit configured to make the backlight turn on in a backlight turn-on period set in the scanning frame period and the suspend frame period, and make the backlight turn off outside the backlight turn-on period, wherein
the backlight turn-on period is set after the scanning period in the scanning frame period.

2. The display device according to claim 1, wherein the backlight turn-on period is set after a time point when a longest response time of the pixel circuit elapses from an end of the scanning period in the scanning frame period.

3. The display device according to claim 2, wherein the backlight drive circuit is configured to make the backlight turn on and off at a frequency higher than a critical flicker frequency.

4. The display device according to claim 2, further comprising a power supply circuit having a heavy load mode in which a power supply conversion efficiency is high at heavy load and a light load mode in which the power supply conversion efficiency is high at light load, and configured to supply a power supply voltage to the panel drive circuit, wherein
the power supply circuit is configured to operate in the heavy load mode in the scanning period and operate in the light load mode in the backlight turn-on period.

5. The display device according to claim 4, wherein the power supply circuit is configured to operate in the light load mode in a period from when a predetermined time elapses from the end of the scanning period to a start of the backlight turn-on period.

6. The display device according to claim 2, wherein the display device has a moving image mode in which only the scanning frame period appears and a low frequency drive mode in which the scanning frame period and the suspend frame period appear in a mixed manner.

7. The display device according to claim 2, wherein the display panel is a liquid crystal panel.

8. The display device according to claim 7, wherein the liquid crystal panel is a lateral electric field type liquid crystal panel.

9. The display device according to claim 8, wherein
the liquid crystal panel includes the plurality of pixel circuits each including a transistor, and
the transistor includes a semiconductor layer formed using an oxide semiconductor including indium, gallium, and zinc.

10. The display device according to claim 2, wherein
the display panel includes the plurality of pixel circuits each including a transistor, and
the transistor includes a semiconductor layer formed using an oxide semiconductor including indium, gallium, and zinc.

11. A method for controlling a display device including a display panel including a plurality of pixel circuits arranged two-dimensionally and a backlight for irradiating a back surface of the display panel with light, and having a scanning frame period and a suspend frame period, the method comprising:
writing a voltage in accordance with a video signal to the pixel circuit in a scanning period set in the scanning frame period; and
making the backlight turn on in a backlight turn-on period set in the scanning frame period and the suspend frame period, and making the backlight turn off outside the backlight turn-on period, wherein
the backlight turn-on period is set after the scanning period in the scanning frame period.

12. The method for controlling the display device according to claim 11, wherein the backlight turn-on period is set after a time point when a longest response time of the pixel circuit elapses from an end of the scanning period in the scanning frame period.

13. The method for controlling the display device according to claim 12, wherein in making the backlight turn on and off, the backlight is made to turn on and off at a frequency higher than a critical flicker frequency.

14. The method for controlling the display device according to claim 12, wherein
the display device further includes a power supply circuit having a heavy load mode in which a power supply conversion efficiency is high at heavy load and a light load mode in which the power supply conversion efficiency is high at light load, and configured to supply a power supply voltage to a panel drive circuit, and
the method further comprises making the power supply circuit operate in the heavy load mode in the scanning period and operate in the light load mode in the backlight turn-on period.

15. The method for controlling the display device according to claim 14, wherein in making the power supply circuit operate, the power supply circuit is made to operate in the light load mode in a period from when a predetermined time elapses from the end of the scanning period to a start of the backlight turn-on period.

16. The method for controlling the display device according to claim 12, wherein the display device has a moving image mode in which only the scanning frame period appears and a low frequency drive mode in which the scanning frame period and the suspend frame period appear in a mixed manner.

17. The method for controlling the display device according to claim 12, wherein the display panel is a liquid crystal panel.

18. The method for controlling the display device according to claim 17, wherein the liquid crystal panel is a lateral electric field type liquid crystal panel.

19. The method for controlling the display device according to claim 18, wherein
the liquid crystal panel includes the plurality of pixel circuits each including a transistor, and
the transistor includes a semiconductor layer formed using an oxide semiconductor including indium, gallium, and zinc.

20. The method for controlling the display device according to claim 12, wherein
the display panel includes the plurality of pixel circuits each including a transistor, and
the transistor includes a semiconductor layer formed using an oxide semiconductor including indium, gallium, and zinc.
